(19) United States
(12) Patent Application Publication
(10) Pub. No.: US 2015/0084083 A1
(43) Pub. Date: Mar. 26, 2015

(54) PHOSPHOR, PRODUCTION METHOD OF THE PHOSPHOR, AND LIGHT EMITTING DEVICE USING THE PHOSPHOR

(71) Applicant: NATIONAL INSTITUTE FOR MATERIALS SCIENCE, Ibaraki (JP)

(72) Inventors: Naoto HIROSAKI, Ibaraki-shi (JP); Kenichi AOYAGI, Tokushima-shi (JP); Takayuki SHINOHARA, Anan-shi (JP); Shoji HOSOKAWA, Tokushima-shi (JP)

(21) Appl. No.: 14/493,570

(22) Filed: Sep. 23, 2014

(30) Foreign Application Priority Data
Sep. 25, 2013 (JP) 2013-198460
Aug. 21, 2014 (JP) 2014-168375

(51) Int. Cl. C09K 11/77; C09K 11/08; H01L 33/50

(52) U.S. Cl. CPC C09K 11/7734; H01L 33/504; C09K 11/0883
USPC 257/98; 252/301.4 F; 428/402

(57) ABSTRACT

A phosphor is provided which includes a general formula represented by CaₓEu_{y}Si₅O₃₋ₐN_{6+b} and the same crystal structure as the crystal represented by Ca₂Si₅O₃N₆. X, y, a and b satisfy

1.4≦x<2.0,

0.2≦y<0.6,

0<a≦1.0,

−0.5<b<1.0, and

1.6≦x+y≦2.0.

### BACKGROUND OF THE INVENTION

1. Field of the Invention

The present invention relates to a phosphor, a production method of the phosphor, and a light emitting device using the phosphor.

2. Description of the Related Art

Phosphors are used in vacuum-fluorescent display (VFD), field emission electron-emitter display (FED), SED (Surface-Conduction Electron-Display), plasma display panel (PDP), cathode-ray tube (CRT), white light emitting diode (LED) device, and the like. In all these uses, in order to make the phosphor emit fluorescent, it is necessary to provide the phosphor with energy for exciting the phosphor. The phosphor is excited by an excitation source, which has high energy (e.g., vacuum ultraviolet ray, ultraviolet ray, visible light ray, and electron beam), and emits visible light ray (e.g., blue, green, yellow, orange or red light). Generally, if the phosphor is subjected to the above excitation source for a long time, the luminance of the phosphor is likely to deteriorate. Accordingly, there is an issue that the phosphor with less deterioration in the luminance is required.

To address this, in other words, to provide a phosphor with less deterioration in emission intensity even under high energy excitation conditions, phosphors have been proposed in recent years which has an inorganic crystal containing nitrogen in a crystal structure thereof as a host crystal, as substitutes for conventional phosphors such as silicate phosphor, phosphate phosphor, aluminate phosphor, borate phosphor, sulfide phosphor, and the oxysulfide phosphor. Examples of the phosphors having the inorganic crystal containing nitrogen can be provided by SIALON phosphor, oxynitride phosphor, nitride phosphor, and the like.

One production process of SIALON phosphor is briefly discussed as follows. First, silicon nitride (Si₃N₄), aluminum nitride (AlN) and europium oxide (Eu₂O₃) are mixed at a predetermined mole ratio, and is placed in a nitrogen atmosphere at 1 atmospheric pressure (0.1 MPa) and temperature of 1700° C. for one hour so that the SIALON phosphor is produced by firing using a hot press method (see Japanese Patent Publication No. JP 3,668,770 B2).

It is reported that the α-SIALON phosphor, which is obtained by the aforementioned process and activated by Eu²⁺ ion, is excited by blue light ranging between 450 and 500 nm inclusive and emits yellow-to-orange light ranging between 550 and 600 nm inclusive. On the other hand, it is known that an emission wavelength can be changed by changing the ratio between Si and Al, and the ratio between oxygen and nitrogen even in the case where the crystal structure of the α-SIALON phosphor is unchanged (Japanese Patent Publications Nos. JP 3,837,551 B2 and JP 4,524,368 B2).

Another known example of SIALON phosphor can be provided by a β-SIALON phosphor as green phosphor that is activated by Eu²⁺. (Japanese Patent Publication No. JP 3,921,545 B2). It is known that an emission wavelength thereof can shift to a shorter wavelength in accordance with oxygen content change even in the case where the crystal structure of the β-SIALON phosphor is unchanged (International Publication No. WO 2007-066,733 A1).

A known example of oxynitride phosphor can be provided by a blue phosphor that has a JEM phase (LaAl(Si_{6-z}Al) N_{10|z}O_{z}) as host crystal activated by Ce³⁺ (International Publication No. WO 2005-019,376 A1). It is known that the excitation wavelength can shift to a longer wavelength and the emission wavelength can shift to a longer wavelength when La is partially substituted with Ca in the case where the crystal structure of this oxynitride phosphor is unchanged.

In addition, a known example of nitride phosphor can be provided by a red phosphor that includes CaAlSiN₃ as host crystal activated by Eu²⁺ (Japanese Patent Publication No. JP 3,837,588 B2). In the case where this phosphor is used in a white LED device, the color rendering property of the white LED device can be improved.

The production process of the CaAlSiN₃ phosphor is briefly discussed as follows. Predetermined amounts of raw material powders of calcium nitride (Ca₃N₂), silicon nitride (Si₃N₄), aluminum nitride (AlN), and europium nitride (EuN) are dispensed and mixed in a glove box in a nitrogen atmosphere. Then, the mixed materials drop into a crucible of boron nitride after passing a 500-μm sieve under their own weight. Subsequently, the crucible is placed in an electric furnace of a graphite resistance heating type, and is burned at temperature of 1800° C. for two hours in a nitrogen atmosphere of 1 MPa by a gas-pressure sintering method. As a result, the CaAlSiN₃ phosphor is produced. It is reported that the CaAlSiN₃ phosphor, which is produced in the aforementioned process, is excited by blue light and emits red light with peak wavelength of approximately 650 nm.

In addition, a phosphor of Ca_{1.5}Ba_{0.5}Si₅N₆O₃:Eu²⁺ is disclosed, which has a composition formula containing Ba, and is excited by light ranging from near-ultraviolet light to blue light whereby emitting yellow-to-red light, by Woon Bae Park, et al. in “Combinatorial chemistry of oxynitride phosphors and discovery of a novel phosphor for use in light emitting diodes, Ca_{1.5}Ba_{0.5}Si₅N₆O₃:Eu²⁺” Journal of Material Chemistry C, 2013, 1, 1832-1839.

As discussed above, the emission color of phosphor depends on the combination of crystal as host crystal and metal ion (activator ion) as solid solution. Also, the emission properties (e.g., emission spectrum and excitation spectrum), the chemical stability and thermal stability of a phosphor depend on the combination of the host crystal and the activator ion. From this viewpoint, it is considered that phosphors that have different host crystals or different activator ions belong to different types. In addition, even in the case where phosphors have the same chemical composition but have different crystal structures, the phosphors have different properties in emission and stability. From this viewpoint, it is considered that these phosphors belong to different types.

Many phosphors can be changed in emission color by substituting their element that composes the phosphors with another element even in the case where the crystal structure of the host crystal in the phosphors is unchanged. For example, a YAG phosphor represented by Y₃Al₅O₁₂:Ce emits yellowish green light. The emission color of the YAG phosphor is changed to yellow by partially substituting Y with Gd in the YAG crystal. Also, the emission color of the YAG phosphor is changed to green by partially substituting Al with Ga in the YAG crystal.

Also, it is known that the composition of a CASN phosphor represented by CaAlSiN₃:Eu can be changed without changing the crystal structure by partially substituting Ca with Sr so that the emission wavelength of the CASN phosphor can shift to a shorter wavelength. As discussed above, it is considered that a phosphor that is subjected to element substitution with its crystal structure being unchanged belongs to the same material group as the original phosphor, which is not subjected to element substitution.

Phosphors have been diligently developed to improve their properties for various types of light emitting devices, for example, to have high emission property as compared with conventional phosphors.

The inventors of the present invention have focused attention on and studied compositions that have the crystal structure represented by Ca₂Si₅O₃N₆ as novel phosphors.

Although many other phosphors having similar chemical composition ratios, which may include the aforementioned phosphors, have been reported, the above phosphors, which have been studied by the inventors, are novel phosphors that has a crystal structure different from the many other phosphors.

The present invention is aimed at addressing the above issue. That is, it is an object to provide a phosphor having the crystal structure represented by Ca₂Si₅O₃N₆ and improved emission properties that has high emission intensity, and chemical and thermal stability properties even in the case where the phosphor is used together with an LED having wavelength of not longer than 470 nm.

### SUMMARY OF THE INVENTION

To achieve the above object, the inventors have diligently studied, and as a result have successfully produced a phosphor that has the following construction, and has an improved absorptance in blue light range ranging between 440 and 460 nm inclusive and emission components ranging from yellow light to red light with high intensity around 600 nm. In summary, the following phosphors according to first and second aspects of the present invention are provided.

A phosphor according to the first aspect of the present invention includes a general formula represented by CaₓEu_{y}Si₅O₃₋ₐN_{6+b} and the same crystal structure as the crystal represented by Ca₂Si₅O₃N₆. X, y, a and b satisfy

1.4≦x<2.0,

0.2≦y<0.6,

0<a≦1.0,

−0.5<b<1.0, and

1.6≦x+y≦2.0.

A phosphor according to the second aspect of the present invention includes a general formula represented by CaₓSr_{z}Eu_{y}Si₅O₃₋ₐN_{6+b} and the same crystal structure as the crystal represented by Ca₂Si₅O₃N₆. X, y, z, a and b satisfy

1.4≦x<2.0,

0.1≦y<0.6,

0.05<z<0.4,

0<a≦1.0,

−0.5<b<1.0, and

1.6≦x+y+z≦2.0.

According to the phosphor, and a production method of the phosphor of the present invention, the phosphor can be provided which can be most strongly excited by light ranging from near-ultraviolet light to visible short-wavelength blue light, in particular from by blue light ranging between 440 and 460 nm inclusive, whereby emitting yellow light to red light, and has less luminescent deterioration even under high temperature conditions. According to a light emitting device using the phosphor of the present invention, the phosphor can be used which has the above effects.

The phosphor produced by the production method according to the present invention has high luminescent, in particular, the present phosphor emits high long-wavelength light ranging from orange light to red light with high luminescent. In addition, the phosphor can be prevented from deteriorating in luminescent intensity even when subjected to excitation sources for a long time. For this reason, an advantageous phosphor can be provided which can be suitably used in fluorescent lamp, vacuum-fluorescent display (VFD), field emission electron-emitter display (FED), plasma display panel (PDP), cathode-ray tube (CRT), white light emitting diode (LED) device, and the like.

The above and further objects of the present invention as well as the features thereof will become more apparent from the following detailed description to be made in conjunction with the accompanying drawings.

### BRIEF DESCRIPTION OF THE DRAWINGS

FIG. 1 is a schematic view showing the crystal structure of Ca₂Si₅O₃N₆ crystal;

FIG. 2 is a graph showing powder X-ray diffraction calculated from the crystal structure of Ca_{1.8}Eu_{0.2}Si₅O_{2.6}N_{5.6} crystal when using CuK α rays;

FIG. 3 is a schematic cross-sectional view showing a light emitting device according to one embodiment of the present invention;

FIG. 4 is a graph showing the reflection spectrums of a comparative example 1, and examples 2 and 4 of the present invention;

FIG. 5 is a graph showing the excitation spectrums of the comparative example 1, and the examples 2 and 4 of the present invention;

FIG. 6 is a graph showing the emission spectrums of the comparative example 1, and the examples 2 and 4 of the present invention;

FIG. 7 is an SEM image of the phosphor according to the comparative example 1;

FIG. 8 is an SEM image of the phosphor according to the example 2; and

FIG. 9 is an SEM image of the phosphor according to the example 4.

### DESCRIPTION OF THE EMBODIMENT(S)

The following description will describe embodiments according to the present invention. It should be appreciated, however, that the embodiments described below are illustrations of a phosphor, a production method of the phosphor, and a light emitting device using the phosphor to give a concrete form to technical ideas of the invention, and a phosphor, a production method of the phosphor, and a light emitting device using the phosphor of the invention are not specifically limited to description below.

The following description will describe a phosphor according to an embodiment with reference to the drawings. The phosphor according to the embodiment has the crystal represented by Ca₂Si₅O₃N₆ or the crystal having the same crystal structure as the crystal represented by Ca₂Si₅O₃N₆, and includes an activator element as solid solution. Specifically, the phosphor according to the embodiment has the composition that is obtained by partially substituting Ca with at least one element selected from the group consisting of Mg, Sr, and Ba. Based on the crystal structure analysis, it is confirmed that the crystal represented by Ca₂Si₅O₃N₆, specifically by composition of Ca_{1.8}Eu_{0.2}Si₅O_{2.6}N_{5.6} is a novel crystal. This novel crystal is represented by the general formula CaₓEu_{y}Si₅O₃₋ₐN_{6+b}. As for the composition ratio, x, y, a and b satisfy

1.4≦x<2.0,

0.2≦y<0.6,

0<a≦1.0,

−0.5<b<1.0, and

1.6≦x+y≦2.0.

X, y, a and b preferably satisfy 1.4≦x≦1.9, 0.2≦y≦0.5, 0.2≦a≦1.0, and −0.5<b≦0.8, respectively. In addition, x, y, a and b more preferably satisfy 1.5≦x≦1.7, 0.25≦y≦0.4, 0.3≦a≦1.0, and −0.5<b≦0.6, respectively. Also, x any preferably satisfy 1.8≦x+y≦2.0.

The novel crystal also can be represented by the general formula CaₓSr_{z}Eu_{y}Si₅O₃₋ₐN_{6+b}. As for the composition ratio, x, y, z, a and b satisfy

1.4≦x<2.0,

0.1≦y<0.6,

0.05<z<0.4,

0<a≦1.0,

−0.5<b<1.0, and

1.6≦x+y≦2.0.

X, y, z, a and b preferably satisfy 1.4≦x≦1.8, 0.1≦y≦0.5, 0.05<z≦0.35, 0.2≦a≦1.0, −0.5<b≦0.8, respectively. In addition, x, y, z, a and b more preferably satisfy 1.4≦x≦1.6, 0.15≦y≦0.35, 0.1≦z≦0.3, 0.4≦a≦1.0, and −0.5<b≦0.6, respectively. Also, x any preferably satisfy 1.8≦x+y+z≦2.0.

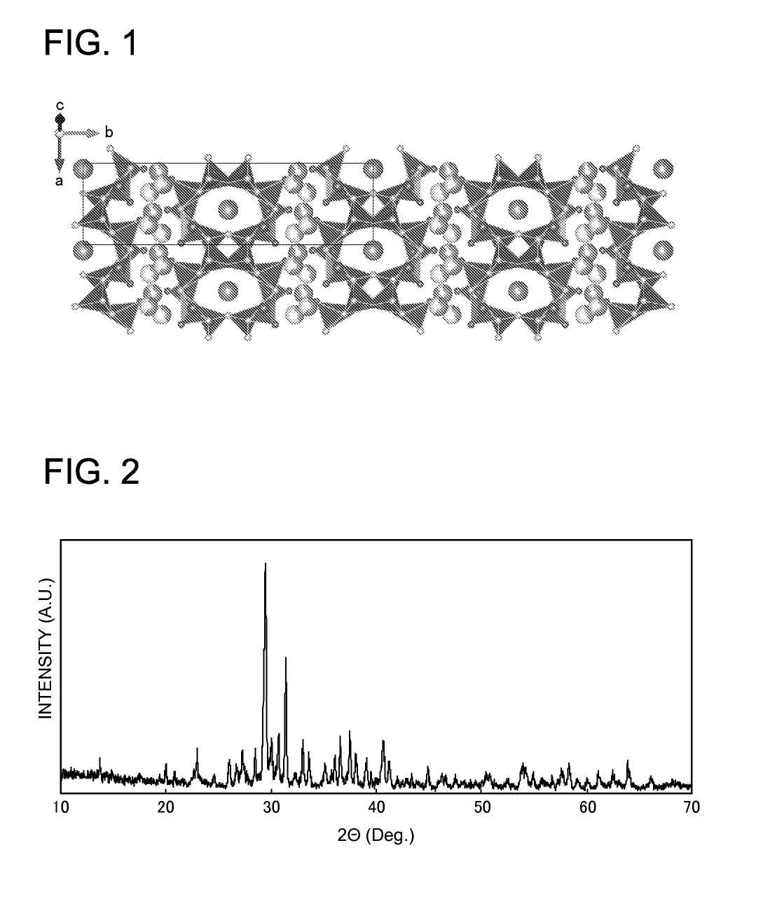

FIG. 1 is a schematic view showing the crystal structure of Ca₂Si₅O₃N₆ crystal. For example, Table 1 shows the crystal structure data of Caₜ₈Eu_{0.2}Si₅O_{2.6}N_{5.6} crystal, which corresponds to an example 1 in analyzed composition. Based on the crystal structure analysis, this crystal belongs to the monoclinic system, and belongs to Cm space group (space group 8 in International Tables for Crystallography). The crystal parameter and the atomic coordinates of this crystal are shown in Table 1. In Table 1, the lattice constants a, b and c represent the lengths of axes of the unit cell, and α, β and γ represent the angles formed by the axes of the unit cell. The atomic coordinates represent values ranging from 0 to 1 as the positions of atoms in the unit cell where each of the lengths of axes of the unit cell are defined as 1. Based on the analyzed result, atoms of Eu, Ca, Si, N and O exist in this crystal, and atoms of Eu can occupy two sites (Eu(1) and Eu(2)). Also, based on the analyzed result, atoms of Ca can occupy eight sites (Ca(1) and Ca(2), Ca(3A) and Ca(3B), Ca(4A) and Ca(4B), and Ca(5A) and Ca(5B)). Also, based on the analyzed result, atoms of Si can occupy ten sites (Si(1) to Si(10)). Also, based on the result, atoms of N can occupy fourteen sites (N(1) to N(14)). Furthermore, based on the analyzed result, atoms of O can occupy six sites (O(1) to O(6)).

TABLE 1

| | Ca_{1.8}Eu_{0.2}Si₅O_{2.6}N_{5.6} | | | |
|---|---|---|---|---|
| Crystal Composition | (Ex. 1) | | | |
| Formula Weight (Z) | 4 | | | |
| Crystal System | Monoclinic System | | | |
| Space Group | Cm | | | |
| Space Group No. | 8 | | | |
| Lattice Constant | a | 7.0627 | Angstrom | |
| | b | 23.757 | Angstrom | |
| | c | 9.6381 | Angstrom | |
| | α | 90 | Degree | |
| | β | 109.008 | Degree | |
| | γ | 90 | Degree | |
| | Atomic Coordinates | | | |
| Atom | x | y | z | Site Occupancy |
| Eu(1) | 0.073382 | 1 | 0.060270 | 0.4 |
| Eu(2) | 1.070538 | 1 | 0.553352 | 0.4 |
| Ca(1) | 0.073382 | 1 | 0.060270 | 0.6 |
| Ca(2) | 1.070538 | 1 | 0.553352 | 0.6 |
| Ca(3A) | −0.398187 | 1.239837 | −0.369211 | 0.880 |
| Ca(3B) | −0.241579 | 1.224987 | −0.249991 | 0.576 |
| Ca(4A) | 0.730269 | 1.227487 | 0.276174 | 0.603 |
| Ca(4B) | 0.479481 | 1.355270 | 0.103150 | 0.146 |
| Ca(5A) | 0.446982 | 1.158258 | −0.092496 | 0.222 |
| Ca(5B) | −0.638769 | 1.228548 | −0.596462 | 0.387 |
| Si(1) | 0.691046 | 1.055820 | 0.747484 | 1 |
| Si(2) | −0.199025 | 1.124928 | 0.021788 | 1 |
| Si(3) | 0.303150 | 1.127508 | 0.144540 | 1 |
| Si(4) | 0.280067 | 1.122476 | 0.688495 | 1 |
| Si(5) | −0.172905 | 1.121772 | −0.461720 | 1 |
| Si(6) | 0.692449 | 1.060115 | 0.190934 | 1 |
| Si(7) | 0.416904 | 1.064559 | −0.070147 | 1 |
| Si(8) | 0.092687 | 1.133779 | 0.362988 | 1 |
| Si(9) | 0.058815 | 1.140981 | −0.130702 | 1 |
| Si(10) | 0.439612 | 1.065256 | 0.403018 | 1 |
| N(1) | 1.017508 | 1 | 0.386371 | 1 |
| N(2) | 0.267154 | 1 | −0.117927 | 1 |
| N(3) | 0.755867 | 1.027849 | 0.619383 | 1 |
| N(4) | 0.373255 | 1 | 0.310463 | 1 |
| N(5) | 0.639388 | 1.068210 | 0.295678 | 1 |
| N(6) | 0.425401 | 1.069378 | −0.371574 | 1 |
| N(7) | 0.823416 | 1.092835 | 0.304555 | 1 |
| N(8) | −0.149247 | 1.099803 | −0.285856 | 1 |
| N(9) | 0.690755 | 1.066893 | −0.078100 | 1 |
| N(10) | 0.292307 | 1.130258 | 0.558469 | 1 |
| N(11) | 0.966664 | 1 | 0.957253 | 1 |
| N(12) | 0.219664 | 1.122627 | 0.249969 | 1 |
| N(13) | 0.058769 | 1.162653 | 0.659831 | 1 |
| N(14) | 0.244974 | 1.126551 | −0.028893 | 1 |
| O(1) | −0.262791 | 1.190790 | 0.005285 | 1 |
| O(2) | 0.073736 | 1.208737 | 0.276747 | 1 |
| O(3) | −0.298570 | 1.195996 | −0.553068 | 1 |
| O(4) | 0.067449 | 1.240213 | −0.022352 | 1 |
| O(5) | 0.360413 | 1.264863 | 0.036103 | 1 |
| O(6) | 0.482165 | 1.162199 | −0.274374 | 1 |

Based on the result from analysis of the data in Table 1, it is found that the crystal of Ca_{1.8}Eu_{0.2}Si₅O_{2.6}N_{5.6} has the structure shown in FIG. 1, and atoms of Ca are held in the framework structure constructed of tetrahedrons each of which is constructed of Si, and O or N. Mg, Sr or Ba elements, which do not serve as activator ion such as Eu, are included in the crystal by partially substituting Ca element with them.

It can be determined whether a crystal belongs to the Ca₂Si₅O₃N₆ group crystal, which relates to this embodiment, or not based on X-ray analysis or neutron beam analysis. Substances according to this embodiment that have the same diffraction result as the Ca₂Si₅O₃N₆ group crystal in the X-ray analysis can be provided by crystals that have their lattice constants or atomic positions different from the Ca₂Si₅O₃N₆ crystal when an element that composes the Ca₂Si₅O₃N₆ crystal is substituted with another element. Examples of crystals that are obtained from the Ca₂Si₅O₃N₆ crystal by substituting an element that composes the Ca₂Si₅O₃N₆ crystal is substituted with another element can be provided by crystals that are obtained from the Ca₂Si₅O₃N₆ crystal by partially or entirely substituting Ca with Mg, Sr, Ba, Mn, Ce, Eu, Pr, Nd, Sm, Tb, Dy, Yb or an element other than Ca. Also, other examples can be provided by crystals that are obtained from the Ca₂Si₅O₃N₆ crystal by partially or entirely substituting Si with Ge, Sn, Ti, Zr, Hf, Al, B, Ga, In, S, Y, La or an element other than Si. Also, other examples can be provided by crystals that are obtained from the Ca₂Si₅O₃N₆ crystal by partially or entirely substituting O and N with fluorine. In the aforementioned substitution, elements are substituted with another element so that the total charge of crystal is neutral. Crystals that have the same crystal structure as the Ca₂Si₅O₃N₆ crystal after substitution are referred to as Ca₂Si₅O₃N₆ group crystal. The emission properties (excitation wavelength, emission wavelength, emission intensity, etc.), chemical stability and thermal stability of the phosphor are changed by substitution of an element with another element. Accordingly, another element for the substitution can be suitably selected depending on use for the phosphor as long as its crystal structure is unchanged.

Although the lattice constants of Ca₂Si₅O₃N₆ group crystal can be changed by substitution of the element that composes the crystal with another element, deficiency of the element, or addition of activator element such as Eu as solid solution, the crystal structure, the sites occupied by atoms, and the atomic positions that are given by the coordinates of the sites are not changed enough to break the chemical bond between the atoms in the framework structure in the Ca₂Si₅O₃N₆ group crystal. In this embodiment, the lattice constants and the atomic coordinates of a sample crystal are obtained by Rietveld analysis of the result of the X-ray diffraction or neutron beam diffraction in the Cm space group, and the lengths of the chemical bonds of Al—N and Si—N (neighbor interatomic distances) of the sample crystal are calculated from the atomic coordinates. It is defined that the sample crystal has the same crystal structure as Ca₂Si₅O₃N₆ crystal if the obtained lattice constants and the calculated lengths of the chemical bonds of the sample crystal fall within the ranges from 95% to 105% of the lattice constants shown in Table 1 and the lengths of the chemical bonds of Ca₂Si₅O₃N₆ crystal calculated from the atomic coordinates shown in Table 1, respectively, in other words, if the difference between the lattice constants or the lengths of the chemical bonds of the sample crystal and Ca₂Si₅O₃N₆ crystal falls within the range of ±5%. The reason to define this criterion is that it is found that the chemical bond of a sample crystal as candidate for Ca₂Si₅O₃N₆ group crystal is broken so that the sample crystal belongs to a type different from Ca₂Si₅O₃N₆ crystal if the difference between the lattice constants or the lengths of the chemical bonds of the sample crystal and Ca₂Si₅O₃N₆ crystal falls out of the range of ±5% based on our experiment.

On the other hand, in the case where the amount of solid solution is small, the following simple determination method can be used for determination of Ca₂Si₅O₃N₆ group crystal. If the lattice constants of a sample crystal that are calculated based on the result of X-ray diffraction measurement agree with the lattice constants in Table 1, or if the main peak positions (2Θ) of the result of X-ray diffraction measurement of the sample crystal agree with the main peak positions that are calculated from the crystal structure data in Table 1, it can be determined that the sample crystal has the same crystal structure as Ca₂Si₅O₃N₆ crystal.

FIG. 2 is the result of powder X-ray diffraction calculated from the crystal structure of Ca_{1.8}Eu_{0.2}Si₅O_{2.6}N_{5.6} crystal when using CuK α rays. Practically, sample crystals are produced as powder. It can be determined by comparison between the powder X-ray diffraction pattern of a produced sample crystal and the pattern show in FIG. 2 whether the sample crystal belongs to the same type as Ca₂Si₅O₃N₆ crystal.

As discussed above, it can be determined in an abbreviated manner by comparison between the pattern of a sample crystal and the pattern show in FIG. 2 whether the sample crystal belongs to the Ca₂Si₅O₃N₆ group crystal. The determination for Ca₂Si₅O₃N₆ group crystal can be made by comparison of about ten strongest diffraction peaks as the aforementioned main peaks. To achieve this, the determination for Ca₂Si₅O₃N₆ group crystal can be made based on the data in Table 1. Also, the Ca₂Si₅O₃N₆ group crystal can be defined in an abbreviated manner by using another monoclinic system. In this case, although the crystal structure is represented by using a space group, lattice constants, and Miller indices different from the aforementioned case, the calculated X-ray diffraction result (e.g., FIG. 2) and the crystal structure (FIG. 1) can be similarly obtained. From this viewpoint, the determination method and the determination result by using another monoclinic system will be the same as the aforementioned case. For this reason, in this embodiment, the X-ray diffraction is analyzed by using a monoclinic system. The method for determining Ca₂Si₅O₃N₆ group crystal based on the data in Table 1 has been schematically described. This method will be described in more detail in the description of embodiments according to the present invention.

(Granular Diameter)

It is preferable that the granular diameter of the phosphor fall within the range not smaller than 1 μm and not greater than 50 μm, and more preferably not smaller than 2 μm and not greater than 30 μm in terms of use in the light emitting device. In addition, it is preferable that the percentage of the phosphor with the above mean granular diameter be high. Also, the grain size distribution is preferably narrow. In the case where a phosphor is used which has less unevenness of granular diameter or grain size distribution, and has a large granular diameter and excellent optical properties, color unevenness can be reduced. Therefore, it is possible to provide a light emitting device with excellent color tone. Accordingly, in the case where the phosphor has a granular diameter in the above range, light absorption and conversion efficiencies can be high. A phosphor with granular diameter smaller than 2 μm is likely to form aggregate.

The granular diameters are measured by particle measurement using electric resistance based on aperture's electrical resistance method (electrical sensing zone method) as Coulter principle. More specifically, after the phosphors are dispersed in a solution, their granular diameters are obtained based on the electric resistances that are generated when grains of the phosphors pass through an aperture of aperture tube.

(Production Method of Phosphor)

The following description will describe a method for producing the phosphor according to this embodiment. Materials for elements to compose the composition of the phosphor can be the elements themselves, or oxide, carbonate, nitride or the like of the elements. These materials are measured to provide a predetermined design composition ratio.

The design composition ratio of the phosphor according to this embodiment is Ca:Sr:Eu:Si:O:N=1.5 to 2:0 to 0.5:0 to 0.5:5:2.2 to 3:5.5 to 6.8. Additives such as flux can be suitably added to the materials. In addition, boron can also be added if necessary.

The materials are mixed in a wet or dry manner by a mixer. The mixer can be a ball mill, which is widely used in commerce. Also, the materials can be pulverized by a pulverizer such as vibrating mill, roll mill or jet mill. In order that the specific surfaces of the materials may fall within certain ranges, the materials can be classified by a wet separator such as settling tank, hydrocyclone or centrifuge, or a dry classifier such as cyclone or air separator. These wet separators and dry classifiers are widely used in commerce.

The mixture of the materials is placed and burned in a crucible or plate-shaped boat made of SiC, quartz, alumina, and boron nitride. The mixture can be burned by a tubular furnace, a small furnace, a high-frequency furnace, a metal furnace, or the like.

In addition, it is preferable that the mixture be burned in an atmosphere of available reducing gas. Specifically, it is preferable that the mixture be burned in an atmosphere of nitrogen, in a mixed atmosphere of nitrogen and hydrogen, in an atmosphere of ammonia, or in a mixed atmosphere of two or more of nitrogen, hydrogen and ammonia (e.g., a mixed atmosphere of nitrogen and ammonia).

Also, it is preferable that the mixture be burned at temperature falling within the range not lower than 1200° C. and not higher than 2000° C., more preferably not lower than 1500° C. and not higher than 1800° C. Also, it is preferable that the mixture be burned for a period falling within the range not shorter than 15 hours and not longer than 200 hours, more preferably not shorter than 20 hours and not longer than 150 hours, most preferably not shorter than 40 and not longer than 150 hours.

Subsequently, the target phosphor powder is obtained by pulverization, dispersion, filtration and the like of the burned product. The target phosphor powder is subjected to solid-liquid separation. Solid-liquid separation is conducted by filtration, suction filtration, pressure filtration, centrifugal separation, decantation, or the like, which is widely used in commerce. The target phosphor powder can be dried by an apparatus that is widely used in commerce (e.g., vacuum dryer, heating dryer, conical dryer, rotary evaporator, etc.) or a method that is widely used in commerce.

Specifically, the phosphor materials are now described. Materials for Ca, Sr, and Ba included in the preparation composition can be the elements themselves, or compounds of metallic compound, oxide, imide, amide, nitride, various kinds of salts (e.g., carbonate, phosphate, silicate, etc.), and the like of these elements. Specifically, SrCO₃, Sr₃N₂, CaCO₃, and the like can be used.

Also, materials for Si in the preparation composition can be the element itself, or compounds of metallic compound, oxide, imide, amide, nitride, various kinds of salts, and the like of Si. Specifically, Si₃N₄, SiO₂, and the like can be used. Also, the elements included in the composition and Si may be previously mixed, and then used. For example, in the case where a compound containing Si is used, the purity of the material of Si is preferably 2N or more. However, the compound containing Si may contain other elements such as Li, Na, K, B and Cu. Also, in order to partially substitute Si with Al, Ga, In, Ge, Sn, Ti, Zr, or Hf, a compound containing Al, Ga, In, Ge, Sn, Ti, Zr, or Hf can be used.

Also, the element Eu itself is preferably used as activator Eu. However, haloid salt, oxide, carbonate, phosphate, silicate, or the like of Eu may be used for activator Eu. Specifically, Eu₂O₃ or the like may be used. In the case where Eu is partially substituted with another element, the composition containing Eu can be mixed with a compound containing a rare earth element or the like as the another element.

In addition, an additional element can be typically added in the form of oxide or hydroxide if necessary. However, the form of additional element is limited to neither oxide nor hydroxide. The additional element may be added in the form of metallic compound, nitride, imide, amide or other inorganic salt, or be contained in previously in other material. It is preferable that the mean granular diameter of a material fall within the range between approximately not smaller than 0.1 μm and not greater than 15 μm, more preferably between approximately not smaller than 0.1 μm and not greater than 10 μm in terms of reactivity with other materials, granular diameter control in and after burning, and the like. If the material has a granular diameter over the above range, the material can be pulverized in an argon atmosphere or nitrogen atmosphere in a glove box so that the granular diameter of this material falls within the above range.

(Light Emitting Device)

The following description describes a light emitting device 100 according to this embodiment that includes the phosphor. The light emitting device according to the present invention includes an excitation light source, and one or more types of phosphors. The excitation light source emits light with peak wavelength falling within the range from near-ultraviolet light to short visible light. The one or more types of phosphors partially absorb light from the excitation light source, and emit fluorescent. At least the phosphor according to this embodiment is contained as the one or more types of phosphors. For example, a lighting apparatus (e.g., fluorescent lamp), a display apparatus (e.g., display and radar), LCD backlight, and the like can be used as the light emitting device. It is preferable to use a light emitting element that emits light in a range from near-ultraviolet light to short wavelength visible light as excitation light source. In particular, semiconductor light emitting elements can be small and highly effective in power consumption, and can emit vivid color light. For this reason, semiconductor light emitting elements can be suitably used. Mercury-vapor lamp or the like, which is used for existing fluorescent lamp, can be also suitably used as another excitation light source.

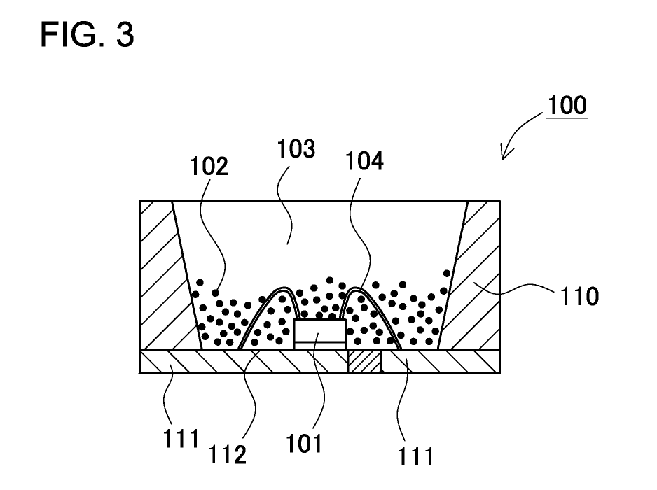

Various shapes of light emitting devices including a light emitting element are known such as so-called bullet type and surface mount type light emitting device. Generally, the bullet type light emitting device refers to a light emitting device that includes a bullet-shaped sealing member for covering a light emitting element and leads. The light emitting element is mounted on one of the leads. The leads serve as terminals to be connected to the outside. The surface mount type light emitting device refers to a light emitting device that includes a light emitting element, a molded body for accommodating the light emitting element, and a sealing member for covering the light emitting element. In addition, another type of light emitting device is known which includes a light emitting element, a plate-shaped circuit board on which the light emitting element is mounted, and a sealing member which contains a phosphor and is formed in a lens shape or the like. The light emitting device 100 according to this embodiment, which is a surface mount type light emitting device, is now described with reference to FIG. 3. FIG. 3 is a cross-sectional view schematically showing the light emitting device 100 according to this embodiment. The light emitting device 100 according to this embodiment includes a package 110 that has a recessed portion, a light emitting element 101, and a sealing member 103 that covers the light emitting element 101. The light emitting element 101 is a gallium nitride group semiconductor device that emits light with short visible wavelength. The recessed portion, which is formed in the package 110, has the bottom and side surfaces. The light emitting element 101 is arranged on the bottom surface 112 of the recessed portion, which is formed in the package 110. The package 110 includes a pair of lead terminals (positive and negative lead terminals) 111. The package is integrally formed with the terminals, and is composed of a thermoplastic resin or thermosetting resin. The light emitting element is electrically connected to the positive and negative lead electrodes 111, which are held in the package 110, through conductive wires 104. The recessed portion is filled with the sealing member 103. The sealing member is formed of resin containing a phosphor 102 that converts light from the light emitting element 101 into light with wavelength different from the light from the light emitting element. It is preferable that the sealing member 103 be formed of a thermosetting resin (e.g., epoxy resin, silicone resin, epoxy-denatured silicone resin, and denatured silicone resin). End parts of the positive and negative lead terminals 111 protrude from exterior side surfaces of the package 110, and are bent so that the end parts extend along the exterior shape of the package 110. The light emitting device 100 is supplied with electric power through the lead terminals 111 from the outside whereby emitting light. The following description will describe components of the light emitting device according to this embodiment.

(Light Emitting Element)

The light emitting element 101 can emit light in the wavelength range from ultraviolet light to visible light. The peak wavelength of light emitted by the light emitting element 101 preferably falls within the wavelength range from 240 to 520 nm, more preferably from 420 to 470 nm. For example, a nitride semiconductor device (InₓAl_{y}Ga_{1-x-y}N, 0≦x, 0≦y, x+y≦1) can be used as the light emitting element 101. In the case where a nitride semiconductor device is used, it is possible to provide a mechanical-shock-resistant stable light emitting device.

(Phosphor)

The phosphor 102 according to this embodiment is distributed in a part of the sealing member 103. According to this embodiment, the sealing member 103 serves not only as a member for protecting the light emitting element 101 and the phosphor 102 from the external environments but also as a wavelength conversion member. In the case where the sealing member including the phosphor is arranged in proximity to the light emitting element 101, the light from the light emitting element 101 can be efficiently converted into light with different wavelength from the light from the light emitting element. As a result, it is possible to provide a light emitting device with good light emission efficiency. However, the member including the phosphor is not limited to be arranged in proximity to the light emitting element. In consideration of influence of heat on the phosphor, the wavelength conversion member containing the phosphor can be spaced at a certain interval from the light emitting element. Also, the phosphor 102 can be entirely mixed in the sealing member 103 at a substantially even ratio whereby reducing color unevenness of light.

Also, two or more types of phosphors 102 can be used. For example, the light emitting device according to this embodiment can include the light emitting element 101 for emitting blue light, the phosphor according to the embodiment excited by the blue light, and the phosphor for emitting red light. In this case, the light emitting device can emit white light with good color rendering. Examples of the phosphor for emitting red light to be used together with the phosphor according to this embodiment can be provided by nitride phosphors such as (Ca₁₋ₓSrₓ)AlSiN₃:Eu (0≦x≦1.0) and (Ca_{1-x-y}SrₓBa_{y})₂Si₅N₈:Eu (0≦x≦1.0, 0≦y≦1.0), halide phosphors such as K₂(Si_{1-x-y}GeₓTi_{y})F₆:Mn (0≦x≦1, 0≦y≦1). In the case where these phosphors for emitting red light are used together with the phosphor according to this embodiment, components corresponding to three primary colors can have wide half-value widths. As a result, the light emitting device can emit warm white light.

Other examples of the phosphors for emitting red light to be used together with the phosphor according to this embodiment can be provided by oxysulfide phosphor activated by Eu such as (La, Y)₂O₂S:Eu, sulfide phosphor activated by Eu such as (Ca, Sr)S:Eu, halophosphate phosphor activated by Eu and Mn such as (Sr, Ca, Ba, Mg)₁₀(PO₄)₆Cl₂:Eu, Mn, oxide phosphor activated by Ce such as Lu₂CaMg₂(Si, Ge)₃O₁₂:Ce, and oxynitride phosphor activated by Eu such as α-SIALON phosphor.

Also, a green or blue phosphor can be used together with the phosphor according to this embodiment. In the case where a phosphor is added which emits green or blue light with a peak wavelength slightly different from the phosphor according to this embodiment, the color reproduction range and the color rendering property can be further improved. Also, in the case where a phosphor is added which absorbs ultraviolet light and emits blue light, a light emitting element that emits ultraviolet light can be used instead of the light emitting element that emits blue light, In this case, the color reproduction range and the color rendering property are improved.

Examples of the phosphors for emitting green light to be used together with the phosphor according to this embodiment can be provided by silicate phosphors such as (Ca, Sr, Ba)₂SiO₄:Eu and Ca₃Sc₂Si₃O₁₂:Ce, chlorosilicate phosphors such as Ca₈MgSi₄O₁₆Cl_{2-δ}:Eu, Mn, oxynitride phosphor such as (Ca,Sr,Ba)₃Si₆O₉N₄:Eu, (Ca,Sr,Ba)₃Si₆O₁₂N₂:Eu and (Ca,Sr,Ba)Si₂O₂N₂:Eu, oxynitride such as β-SIALON of Si_{6-z}Al_{z}O_{z}N_{8-z}:Eu (0<z<4.2), aluminate phosphor activated by Ce such as (Y, Lu)₃(Al,Ga)₅O₁₂:Ce, sulfide phosphor activated by Eu such as SrGa₂S₄:Eu, and oxide phosphor such as CaSc₂O₄:Ce.

Examples of the phosphors as phosphor for emitting blue light to be used together with the phosphor according to this embodiment can be provided by aluminate phosphor activated by Eu such as (Sr, Ca, Ba)Al₂O₄:Eu, (Sr,Ca,Ba)₄Al₁₄O₂₅:Eu, (Ba, Sr, Ca)MgAl₁₀O₁₇:Eu, and BaMgAl₁₄O₂₅:Eu, Tb, Sm, aluminate phosphor activated by Eu, Mn such as (Ba, Sr, Ca)MgAl₁₀O₁₇:Eu, Mn, thiogallate phosphor activated by Ce such as SrGa₂S₄:Ce and CaGa₂S₄:Ce, silicate phosphor activated by Eu such as (Ba, Sr, Ca, Mg)₂SiO₄:Eu, halophosphate phosphor activated by Eu such as (Sr, Ca, Ba, Mg)₁₀(PO₄)₆Cl₂:Eu, and silicate phosphor activated by Eu such as (Ca, Sr, Ba)₃MgSi₂O₈:Eu.

(Sealing Member)

The sealing member 103 is formed of transparent resin or glass resin. The recessed portion of the light emitting device 100 is filled with the transparent resin or glass resin so that the light emitting element 101 is covered by the transparent resin or glass resin. In terms of ease of production, the sealing member is preferably formed of transparent resin. Silicone resin compositions can be preferably used as the transparent resin. However, insulating resin compositions such as epoxy resin composition and acrylic resin composition may be used. An additive member can be suitably included together with the phosphor 102 in the sealing member 103. For example, a light diffusion member can be added to the sealing member. In this case, the directivity from the light emitting element can be reduced so that the viewing angle can be increased.

### Examples 1 to 12, and Comparative Examples 1 and 2

Phosphors according to examples 1 to 12, and comparative examples 1 and 2 are now described. The phosphors according to the comparative examples 1 and 2 are produced by using α-silicon nitride powder, silicon dioxide powder, calcium oxide powder, barium oxide powder, and europium oxide powder as materials.

Table 2 shows the design composition of the phosphors according to the examples 1 to 12 and the comparative examples 1 and 2. The aforementioned materials of the phosphors according to the comparative examples 1 and 2 are mixed in mortar at the composition ratios shown in Table 2. Thus, mixtures of the materials are prepared. In addition, in order to facilitate burning the mixtures, inorganic compounds that exhibit a liquid phase at temperature not higher than the burning temperature may be added to the compound of metal shown in Table 2. Examples of the inorganic compounds can be provided by fluoride, chloride and phosphate of Li, Na, K, Cs, Rb, Mg, Ca, Sr or Ba, or NH₃. Other examples of the inorganic compounds can be provided by one of fluoride, chloride and phosphate of at least one selected from the group consisting of Li, Na, K, Cs, Rb, Mg, Ca, Sr, Ba and NH₃, or a mixture of two or more of the fluoride, chloride and phosphate.

TABLE 2

| | Design Composition | | | | | | |
|---|---|---|---|---|---|---|---|
| | Ca | Sr | Ba | Si | O | N | Eu |
| Com. Ex. 1 | 1.56 | 0 | 0.38 | 5 | 3 | 6 | 0.06 |
| Com. Ex. 2 | 1.9 | 0 | 0 | 5 | 3 | 6 | 0.1 |
| Ex. 1 | 1.8 | 0 | 0 | 5 | 3 | 6 | 0.2 |
| Ex. 2 | 1.7 | 0 | 0 | 5 | 3 | 6 | 0.3 |
| Ex. 3 | 1.7 | 0 | 0 | 5 | 2.5 | 6.3 | 0.3 |
| Ex. 4 | 1.7 | 0 | 0 | 5 | 2 | 6.7 | 0.3 |
| Ex. 5 | 1.7 | 0 | 0 | 5 | 1.8 | 6.8 | 0.3 |
| Com. Ex. 3 | 1.9 | 0 | 0 | 5 | 2 | 6.7 | 0.1 |
| Ex. 6 | 1.8 | 0.1 | 0 | 5 | 2 | 6.7 | 0.1 |
| Ex. 7 | 1.7 | 0.2 | 0 | 5 | 2 | 6.7 | 0.1 |
| Ex. 8 | 1.6 | 0.3 | 0 | 5 | 2 | 6.7 | 0.1 |
| Ex. 9 | 1.8 | 0 | 0 | 5 | 2 | 6.7 | 0.2 |
| Ex. 10 | 1.7 | 0.1 | 0 | 5 | 2 | 6.7 | 0.2 |
| Ex. 11 | 1.6 | 0.2 | 0 | 5 | 2 | 6.7 | 0.2 |
| Ex. 12 | 1.6 | 0.1 | 0 | 5 | 2 | 6.7 | 0.3 |

Each of the mixtures of the materials is contained in a cylindrical boron nitride vessel. The vessel is placed in a graphite resistance heater as electric furnace. Subsequently, the furnace is filled with nitrogen, and the temperature is raised to 1650° C. at pressure of 0.9 Mpa in the furnace. The mixture of the materials is held at this temperature for five hours. The obtained burned product is pulverized. Thus, powder of each of the phosphors according to the comparative examples 1 and 2 is produced.

Based on powder X-ray diffraction analysis, the powder of the phosphor according to the comparative example 1 has the same crystal structure as Ca₂Si₅O₃N₆ crystal, while the powder of the phosphor according to the comparative example 2 is CaSi₂O₂N₂.

Emission spectrum of the phosphor excited by excitation light with wavelength 460 nm is measured in the wavelength range not shorter than 480 nm and not longer than 830 nm. The emission intensity of each phosphor is defined as relative value where the emission intensity of the phosphor according to the comparative example 1 is defined as 100%.

Excitation spectrum of the phosphor is measured in the wavelength range not shorter than 220 nm and not longer than 570 nm. From the measured excitation spectrum, the maximum intensity wavelength can be obtained which provides the maximum emission intensity of the phosphor. The excitation spectrum of each phosphor is normalized where the excitation intensity of the phosphor at the maximum intensity wavelength is defined as 100%.

Reflection spectrum of phosphor is measured in the wavelength range not shorter than 420 nm and not longer than 720 nm. The reflection spectrum of each phosphor is measured where CaHPO₄ is used for the measurement reference. The absorptance of the phosphor is defined by 100−(reflectivity of phosphor at parameter of wavelength).

### Examples 1 and 2

The phosphors according to the examples 1 and 2 are now described. Except that the materials shown in the comparative examples 1 and 2 are mixed at the composition ratios of the examples 1 and 2 shown in Table 2, the mixtures of the examples 1 and 2 are burned and pulverized similarly to the comparative examples 1 and 2, and are then dispersed and classified in a wet manner.

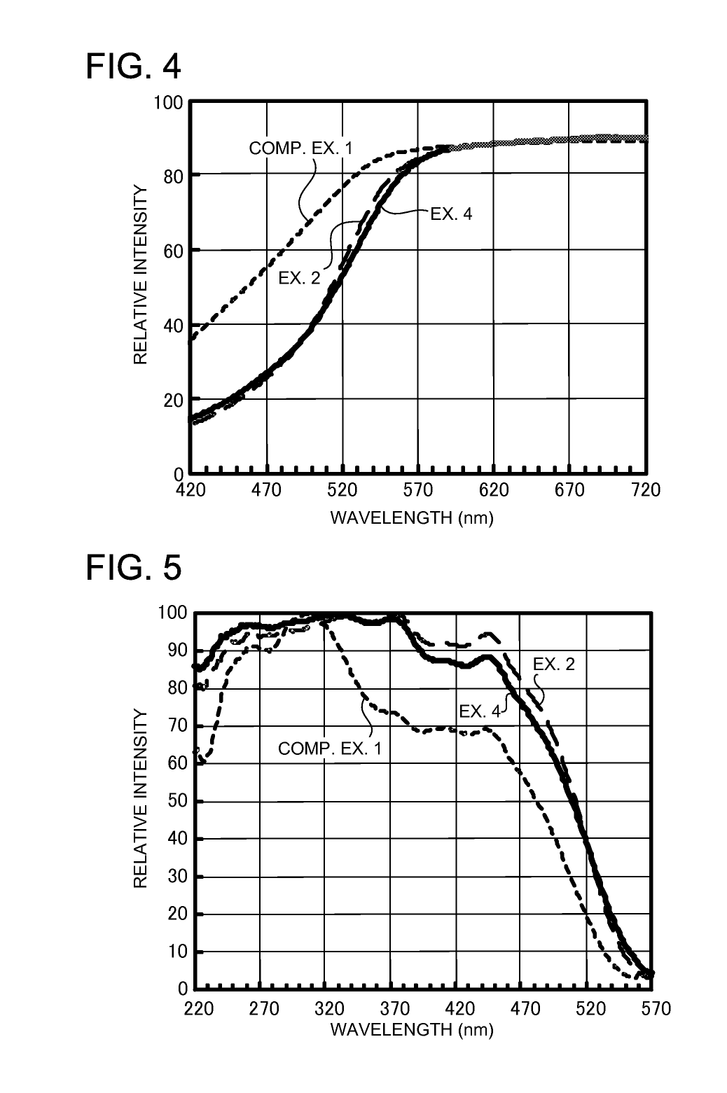

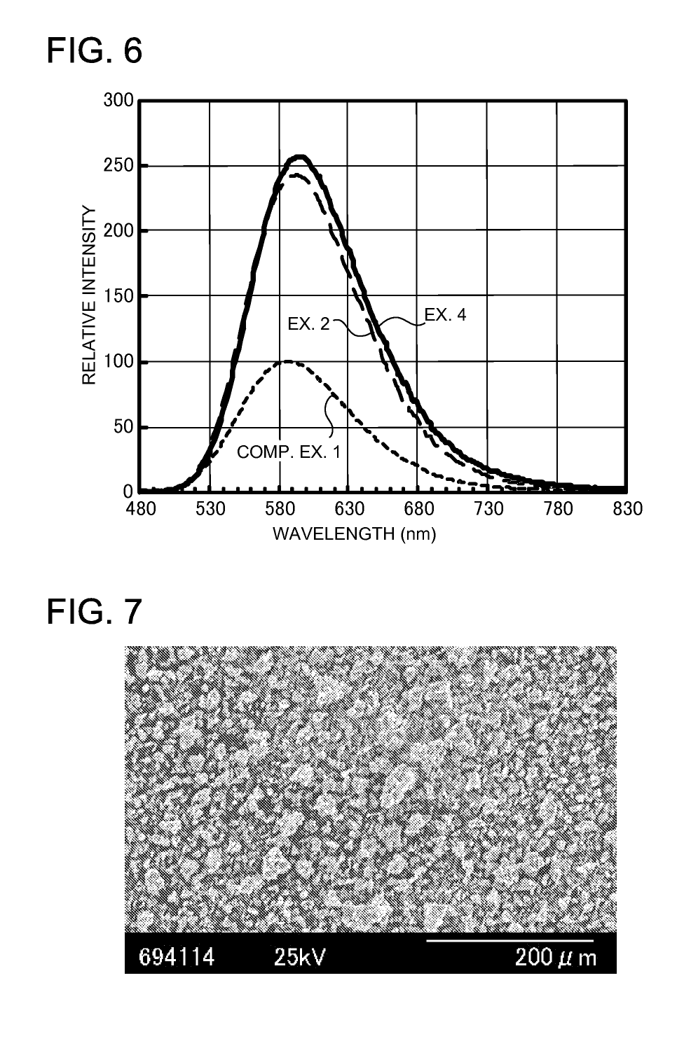

Table 3 shows O/(O+N) ratio, and produced phase obtained based on powder X-ray diffraction result. Table 4 shows absorptance at 460 nm, the reflectivity at 580 nm, excitation coefficient at 460 nm, and emission intensity and emission peak wavelength in excitation at 460 nm. FIG. 4 shows the reflection spectrums. FIG. 5 shows the excitation spectrums. FIG. 6 shows the emission spectrums.

TABLE 3

| | O/(O + N) Ratio | Powder X-Ray Diffraction Result |
|---|---|---|
| Com. Ex. 1 | 0.33 | Ca₂Si₅O₃N₆ |
| Com. Ex. 2 | 0.33 | CaSi₂O₂N₂ |
| Ex. 1 | 0.33 | Ca₂Si₅O₃N₆ |
| Ex. 2 | 0.33 | Ca₂Si₅O₃N₆ |
| Ex. 3 | 0.28 | Ca₂Si₅O₃N₆ |
| Ex. 4 | 0.23 | Ca₂Si₅O₃N₆ |
| Ex. 5 | 0.21 | Ca₂Si₅O₃N₆ |

TABLE 4

| | Absorp- | Reflect- | Excitation | Emission | Emission |
|---|---|---|---|---|---|
| | tance | ivity | Coef. | Peak | Peak |
| | (460 nm) | (580 nm) | (460 nm) | Wavelength | Intensity |
| Com. Ex. 1 | 48.8 | 87.4 | 62.3 | 587 | 100 |
| Com. Ex. 2 | 56.0 | 91.8 | 87.2 | 596 | 135 |
| Ex. 1 | 81.8 | 79.9 | 87.7 | 592 | 203 |
| Ex. 2 | 77.8 | 83.9 | 87.2 | 593 | 243 |
| Ex. 3 | 73.7 | 87.9 | 83.4 | 593 | 238 |
| Ex. 4 | 76.3 | 85.8 | 81.1 | 593 | 257 |
| Ex. 5 | 80.0 | 83.5 | 85.3 | 595 | 261 |

As shown in Table 3, the phosphors according to the examples 1 and 2 have a single phase of Ca₂Si₅O₃N₆ crystal structure based on powder X-ray diffraction result. In the case where the alkaline earth metal that is contained in the phosphor is only Ca ion as in the cases of the comparative example 2, and the examples 1 and 2, the requirement for producing the Ca₂Si₅O₃N₆ crystal structure is that not smaller than 10 mol % of Ca ion is substituted with Eu ion, which serves as luminescent center.

As shown in Table 4 and FIGS. 4 to 6, the absorptance of the phosphor according to the example 2 is substantially improved at wavelength of not longer than 460 nm compared with that of the comparative example 1, and specifically the absorptance of the phosphor according to the example 2 is not smaller than 70% at wavelength of not longer than 460 nm. Also, the excitation coefficient of the phosphor according to the example 2 is substantially improved in the wavelength range not shorter than 320 nm and not longer than 570 nm, while the excitation coefficient of the phosphor according to the example 2 is not smaller than 80% at wavelength of not longer than 460 nm. The intensity of emission spectrum is correspondingly increased. That is, it is found that, in the case where the alkaline earth metal that is contained in the phosphor is only Ca as in the examples 1 and 2, absorption and excitation can be facilitated in the short wavelength range of visible light as compared with the case where the alkaline earth metal that is contained in the phosphor is Ca and Ba as in the comparative example 1. For example, even when illuminated by a blue-range light source such as blue LED, the phosphor that contains only Ca as alkaline earth metal can be excited and emit light.

### Examples 3 to 5

The phosphors according to the examples 3 to 5 are now described. Except that α-silicon nitride powder, silicon dioxide powder, calcium oxide powder, calcium nitride powder, and europium oxide powder as materials are prepared at the composition ratios of the examples 3 to 5 shown in Table 2 and mixed to obtain mixtures with adjusted amounts of O and N, the phosphors according to the examples 3 to 5 are produced by this mixing, burning, pulverization, and wet dispersion and classification similar to the comparative example 1.

Based on X-ray diffraction result of the powder obtained in the examples 3 to 5, all of the phosphors according to the examples 3 to 5 have a single phase of Ca₂Si₅O₃N₆ as shown in Table 3. On the other hand, if the amount of N is higher than the case of the composition of the example 5, a secondary phase of Ca₂Si₅N₅ appears. That is, it is found that the requirement for producing a single phase of Ca₂Si₅O₃N₆ crystal structure is to adjust amounts of O and N so as to satisfy 0.21≦O/(O+N)≦0.33.

As shown in Tables 3 and 4, and FIGS. 4 to 6, the absorptances of the phosphors according to the examples 3 to 5 are substantially improved in the wavelength range of not longer than 460 nm compared with that of the comparative example 1. Also, the excitation coefficients of the phosphors according to the examples 3 to 5 are substantially improved in the wavelength range not shorter than 320 nm and not longer than 570 nm. The intensities of emission spectrums of the phosphors according to the examples 3 to 5 are correspondingly increased. In particular, the emission intensity is the highest at the design composition corresponding to approximately O/(O+N)=0.23 in the example 4 among the phosphors having the single phase of Ca₂Si₅O₃N₆ crystal structure.

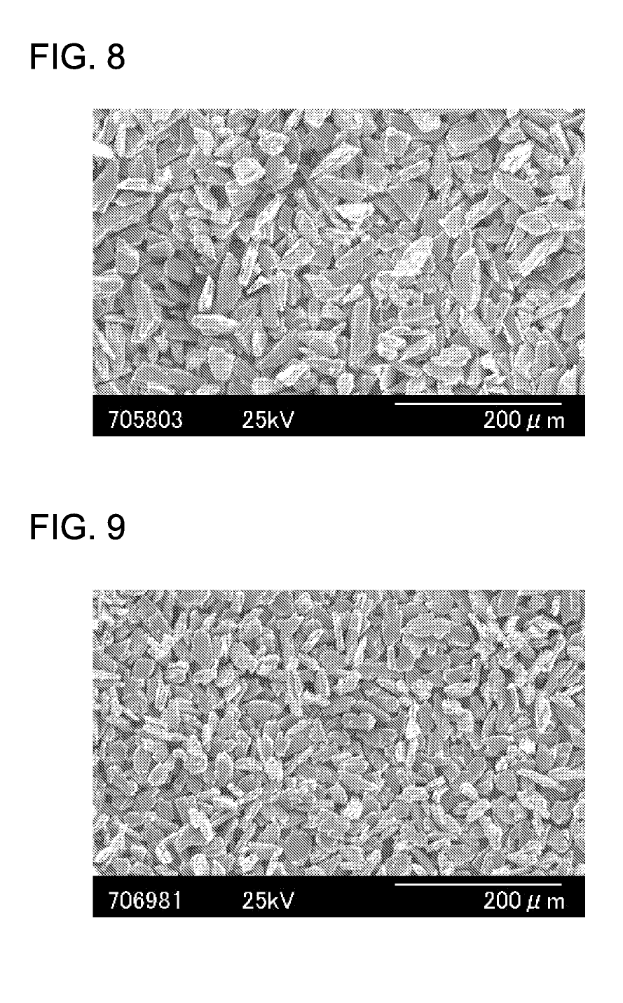

FIGS. 7, 8 and 9 show SEM images of the phosphors according to the comparative example 1, the example 2 and the example 4, respectively. Also, Table 5 shows mean granular diameters and aspect ratios of the phosphors according to the comparative example 1, the example 2 and the example 4. The mean granular diameters (μm) are measured by particle measurement using electric resistance based on aperture's electrical resistance method (electrical sensing zone method) as Coulter principle. More specifically, after the phosphors are dispersed in a solution, their granular diameters are obtained based on the electric resistances that are generated when grains of the phosphors pass through an aperture of aperture tube. The aspect ratios are measured by using a particle image analysis apparatus. Specifically, grain sizes and grain shape of 5000 grains are measured based on the image analysis technology, and the aspect ratio of a grain is obtained by dividing the minor axis by the major axis of the grain. The phosphors according to the examples 1 to 5 are large in granular diameter as compared with the comparative example 1. In particular, the mean granular diameter of the phosphor according to the example 4 may vary from not smaller than 10 μm and not greater than 20 μm. In consideration of the mean granular diameters of the phosphors according to the examples 2 and 4, the phosphor according to the present invention preferably has a mean granular diameter falling within the range not smaller than 10 μm and not greater than 30 μm. Phosphors having mean granular diameter within this range can be practically used for LED devices. In the case where silicon dioxide is used as the material, phosphor grains often will be large in grain size. However, it is found that the granular diameter can be controlled in the case where silicon dioxide is not used. In addition, it is found that the aspect ratio of the grains of the phosphor according to the present invention is preferably not greater than 0.7 according to the comparison between the comparative example 1, and the examples 2 and 4.

TABLE 5

| | Mean Granular Dia. (μm) | Aspect Ratio |
|---|---|---|
| Com. Ex. 1 | 10.3 | 0.73 |
| Ex. 2 | 23.2 | 0.67 |
| Ex. 4 | 19.5 | 0.64 |

### Comparative Example 3 and Examples 6 to 12

The phosphors according to a comparative example 3, and the examples 6 to 12 are now described. Except that α-silicon nitride powder, silicon dioxide powder, calcium oxide powder, strontium oxide, and europium oxide powder as materials are prepared at the composition ratios of the comparative example 3 and the examples 6 to 12 shown in Table 2 and mixed to obtain mixtures with adjusted amounts of Ca, Sr and Eu, the phosphors according to the comparative example 3 and the examples 6 to 12 are produced by this mixing, burning, pulverization, and wet dispersion and classification similar to the comparative example 1.

Table 6 shows (Sr+Eu)/(Ca+Sr+Eu) ratio, and the powder X-ray diffraction result of the produced powder in the comparative example 3 and the examples 6 to 12. Table 7 shows absorptance at 460 nm, the reflectivity at 580 nm, excitation coefficient at 460 nm, and emission intensity and emission peak wavelength in excitation at 460 nm in the comparative example 3 and the examples 6 to 12.

TABLE 6

| | (Sr + Eu)/(Ca + Sr + Eu) | powder X-Ray |
|---|---|---|
| | [mol %] | Diffraction Result |
| Com. | 5 | CaSi₂O₂N₂, |
| Ex. 3 | | Ca₂Si₅N₈, |
| | | Ca₂Si₅O₃N₆ |
| Ex. 6 | 10 | Ca₂Si₅O₃N₆ |
| Ex. 7 | 15 | Ca₂Si₅O₃N₆ |
| Ex. 8 | 20 | Ca₂Si₅O₃N₆ |
| Ex. 9 | 10 | Ca₂Si₅O₃N₆ |
| Ex. 10 | 15 | Ca₂Si₅O₃N₆ |
| Ex. 11 | 20 | Ca₂Si₅O₃N₆ |
| Ex. 12 | 20 | Ca₂Si₅O₃N₆ |

TABLE 7

| | Absorp- | Reflectiv- | Excitation | Emission | Emission |
|---|---|---|---|---|---|
| | tance | ity | Coef. | Wave- | Peak Intensity |
| | (460 nm) | (580 nm) | (460 nm) | length (nm) | (%) |
| Com. | 67.8 | 89.6 | 94.4 | 602 | 132 |
| Ex. 3 | | | | | |
| Ex. 6 | 66.2 | 81.4 | 74.7 | 594 | 192 |
| Ex. 7 | 65.0 | 81.0 | 75.7 | 591 | 202 |
| Ex. 8 | 66.6 | 80.3 | 73.8 | 591 | 208 |
| Ex. 9 | 74.6 | 83.8 | 81.0 | 593 | 249 |
| Ex. 10 | 72.9 | 83.7 | 79.7 | 593 | 237 |
| Ex. 11 | 79.0 | 80.5 | 83.0 | 595 | 248 |
| Ex. 12 | 86.9 | 71.7 | 84.2 | 602 | 219 |

Based on the powder X-ray diffraction result of the burned product powder, as shown in Table 6, CaSi₂O₂N₂, Ca₂Si₅N₈, and Ca₂Si₅O₃N₆ crystal structures are mixed in the powder obtained in the comparative example 3, while the powder obtained in each of the examples 6 to 12 has a single phase of Ca₂Si₅O₃N₆ crystal structure. That is, it is conceivable that the Ca elements are substituted with the Sr and Eu elements as solid solution so that the Sr and Eu ions are positioned at some of the Ca sites. It can be considered that a requirement for producing a single phase of Ca₂Si₅O₃N₆ crystal structure is that the solid solution amount of (Sr+Eu) falls within the range not smaller than 5 mol % and not greater than 25 mol %.

As shown in Tables 6 and 7, the absorption of the powder in each of the examples 6 to 12, which has a single phase of Ca₂Si₅O₃N₆ crystal structure, is substantially improved at wavelength of not longer than 460 nm as compared with the comparative example 1. Also, the excitation coefficients of the phosphors according to the examples 6 to 12 are substantially improved in the wavelength range not shorter than 320 nm and not longer than 570 nm. The intensities of emission spectrums of the phosphors according to the examples 6 to 12 are correspondingly increased. In particular, the absorptance, reflectivity, and excitation coefficient of the powder in the example 11 are not smaller than 75% at wavelength of not longer than 460 nm, not smaller than 80% at wavelength of not shorter than 580 nm, and not smaller than 80% at wavelength of not longer than 460 nm, respectively. Accordingly, it is found that, even when illuminated by a blue-range light source such as blue LED, the powder in the example 11 can be excited and emit light. Here, the excitation coefficient of a phosphor is a relative intensity where the highest intensity is defined as 100% in the range not shorter than 250 nm and not longer than 600 nm in the excitation spectrum of the phosphor. According to the data of the reflectivity (580 nm) and excitation coefficient (460 nm) shown in Tables 4 and 7, and the tendency of the wavelength dependency of the reflectivity and excitation coefficient shown in FIGS. 4 and 5, it is confirmed that the peak wavelengths of the phosphors according to the present invention range not shorter than 590 nm and not longer than 610 nm, that the reflectivities at wavelength of not shorter than 580 nm are not lower than 70%, and that the excitation coefficients at wavelength of not longer than 460 nm are not lower than 70%. In addition, according to the data of absorptance (460 nm) in Tables 4 and 7, it is confirmed that the absorptance of the phosphor according to the present invention in the wavelength not shorter than 460 nm is not smaller than 65%.

Table 8 shows the analyzed compositions of the phosphors according to the comparative examples 1 to 3 and the examples 1 to 12. The phosphor composition is analyzed for Ca, Sr, Ba and Eu by ICP-AES (inductively coupled plasma atomic emission spectroscopy), for Si by gravimetric analysis and ICP-AES, and for O and N by oxygen and nitrogen analyzer. Based on the comparison between the analyzed compositions and the design compositions shown in Table 2, there are small differences of O and N amounts between them, while the amounts of other elements in the analyzed compositions and the design compositions substantially agree with each other.

TABLE 8

| | Analyzed Composition | | | | | | |
|---|---|---|---|---|---|---|---|
| | Ca | Sr | Ba | Si | O | N | Eu |
| Com. Ex. 1 | 1.6 | 0.0 | 0.4 | 5.0 | 2.6 | 5.8 | 0.1 |
| Com. Ex. 2 | 2.0 | 0.0 | 0.0 | 5.0 | 2.4 | 5.4 | 0.1 |
| Ex. 1 | 1.8 | 0.0 | 0.0 | 5.0 | 2.6 | 5.6 | 0.2 |
| Ex. 2 | 1.5 | 0.0 | 0.0 | 5.0 | 2.1 | 6.1 | 0.4 |
| Ex. 3 | 1.5 | 0.0 | 0.0 | 5.0 | 2.1 | 6.2 | 0.4 |
| Ex. 4 | 1.6 | 0.0 | 0.0 | 5.0 | 2.1 | 6.1 | 0.3 |
| Ex. 5 | 1.6 | 0.0 | 0.0 | 5.0 | 2.0 | 6.0 | 0.4 |
| Com. Ex. 3 | 1.9 | 0.0 | 0.0 | 5.0 | 2.2 | 6.2 | 0.1 |
| Ex. 6 | 1.6 | 0.2 | 0.0 | 5.0 | 2.0 | 6.2 | 0.2 |
| Ex. 7 | 1.6 | 0.2 | 0.0 | 5.0 | 2.1 | 6.1 | 0.1 |
| Ex. 8 | 1.5 | 0.3 | 0.0 | 5.0 | 2.0 | 5.9 | 0.1 |
| Ex. 9 | 1.6 | 0.0 | 0.0 | 5.0 | 2.0 | 6.1 | 0.3 |
| Ex. 10 | 1.6 | 0.1 | 0.0 | 5.0 | 2.0 | 6.1 | 0.2 |
| Ex. 11 | 1.5 | 0.2 | 0.0 | 5.0 | 2.1 | 6.1 | 0.2 |
| Ex. 12 | 1.4 | 0.2 | 0.0 | 5.0 | 2.1 | 6.1 | 0.3 |

According to Tables 4, 7, and 8, it is confirmed that, in particular, emission intensity is increased when x, y, a, and b in the general formula CaₓEu_{y}Si₅O₃₋ₐN_{6+b} satisfy 1.5≦x≦1.7, 0.25≦y≦0.4, 0.3≦a≦1.0, and −0.5≦b≦0.6, respectively, in other words, in the examples 2 to 5, and 9, as compared with the comparative examples and the example 1.

Also, according to Tables 4, 7, and 8, it is confirmed that, in particular, emission intensity is increased when x, y, z, a, and b in the general formula CaₓSr_{z}Eu_{y}Si₅O₃₋ₐN_{6+b} satisfy 1.4≦x≦1.6, 0.15≦y≦0.35, 0.1≦z≦0.3, 0.4≦a≦1.0, and −0.5<b≦0.6, respectively, in other words, in the examples 9 to 11, as compared with the comparative examples and other example 6 to 8 and 12.

### Comparative Example 4 and Example 13

Ca₂Si₅O₃N₆ as the example 4 and (Ca, Sr)₂Si₅O₃N₆ as the example 11 are higher in the emission intensity than (Ca, Ba)₂Si₅O₃N₆ as the comparative example 1. From this viewpoint, a white LED device according to an example 13 is produced which includes a YAG (Y₃(Al, Ga)₅O₁₂:Ce) phosphor and the phosphor according to the example 4. The characteristics of the white LED device are evaluated. Also, a white LED device according to a comparative example 4 is produced which includes a YAG (Y₃(Al, Ga)₅O₁₂:Ce) phosphor and a phosphor of Ca₂Si₅N₅:Eu.

Table 9 shows the phosphor types included in the white LED device, and the color temperature and relative intensity of the white LED device. The relative intensity is a relative value where the luminous flux of the device according to the comparative example 4 is defined as 100% as shown in Table 9. Specifically, the white LED device according to the comparative example 4 includes a Y₃(Al, Ga)₅O₁₂:Ce phosphor and the Ca₂Si₅N₃:Eu phosphor, while the white LED device according to the example 13 includes a Y₃(Al, Ga)₅O₁₂:Ce phosphor and a phosphor having the Ca₂Si₅O₃N₆:Eu crystal structure. The ratio between the phosphors included in each white LED device is adjusted so that the color temperature of the device is 5000 K.

TABLE 9

| | | | Color Temp. | Relative Lumi- |
|---|---|---|---|---|
| | Phosphor 1 | Phosphor 2 | (K) | nous Flux (%) |
| Com. | Y₃(Al,Ga)₅O₁₂: | Ca₂Si₅N₈: | 5000 | 100 |
| Ex. 4 | Ce | Eu | | |
| Ex. 13 | Y₃(Al,Ga)₅O₁₂: | Phosphor of | 5000 | 103 |
| | Ce | Ex. 4 | | |

As shown in Table 9, the luminous flux relative value of the white LED device with the aforementioned phosphor combination according to the example 13 is 103% where the luminous flux of the white LED device with the aforementioned phosphor combination according to the comparative example 4 is defined as 100%. Accordingly, it is found that the white LED device with the phosphor according to this embodiment has higher performance than the white LED device with the existing phosphor.

The phosphor according to the present invention can be suitably used for light sources for lighting, and the like. The phosphor can be produced by the production method according to the present invention. The light emitting device using the phosphor according to the present invention can be suitably used for light sources for lighting, and the like. The phosphor according to the present invention can be used to be excited by vacuum ultraviolet ray, electron beam, or the like as well as visible light and ultraviolet light, and be used in fluorescent lamp, vacuum-fluorescent display (VFD), field emission display (FED), plasma display panel (PDP), cathode-ray tube (CRT), white light emitting diode (LED), and the like.

It should be apparent to those with an ordinary skill in the art that while various preferred embodiments of the invention have been shown and described, it is contemplated that the invention is not limited to the particular embodiments disclosed, which are deemed to be merely illustrative of the inventive concepts and should not be interpreted as limiting the scope of the invention, and which are suitable for all modifications and changes falling within the scope of the invention as defined in the appended claims. The present application is based on Applications No. 2013-198,460 filed in Japan on Sep. 25, 2013, and No. 2014-168,375 filed in Japan on Aug. 21, 2014, the contents of which are incorporated herein by references.

What is claimed is:

1. A phosphor including a general formula represented by CaₓEu_{y}Si₅O₃₋ₐN_{6+b} and the same crystal structure as the crystal represented by Ca₂Si₅O₃N₆,
wherein x, y, a and b satisfy
1.4≦x<2.0,
0.2≦y<0.6,
0<a≦1.0,
−0.5<b<1.0, and
1.6≦x+y≦2.0.

2. The phosphor according to claim 1, wherein x, y, a and b satisfy 1.5≦x≦1.7, 0.25≦y≦0.4, 0.3≦a≦1.0, and −0.5<b≦0.6, respectively.

3. A phosphor including a general formula represented by CaₓSr_{z}Eu_{y}Si₅O₃₋ₐN_{6+b} and the same crystal structure as the crystal represented by Ca₂Si₅O₃N₆,
wherein x, y, z, a and b satisfy
1.4≦x<2.0,
0.1≦y<0.6,
0.05<z<0.4,
0<a≦1.0,
−0.5<b<1.0, and
1.6≦x+y≦2.0.

4. The phosphor according to claim 3, wherein x, y, z, a and b satisfy 1.4≦x≦1.6, 0.15≦y≦0.35, 0.1≦z≦0.3, 0.4≦a≦1.0, and −0.5<b≦0.6, respectively.

5. The phosphor according to claim 1, wherein the absorption range of the phosphor ranges from near-ultraviolet light to short visible light, and the emission peak wavelength of the phosphor falls within the range not shorter than 590 nm and not longer than 610 nm when the phosphor absorbs the light in said range.

6. The phosphor according to claim 1, wherein the absorptance of the phosphor is not smaller than 65% in the wavelength range of not longer than 460 nm, and the reflectivity of the phosphor is not smaller than 70% in the wavelength range of not shorter than 580 nm.

7. The phosphor according to claim 1, wherein the ratio between O and (O+N) of the phosphor satisfies
0.21≦O/(O+N)≦0.33.

8. The phosphor according to claim 1, wherein the mean granular diameter of the phosphor falls within the range not smaller than 10 μm and not greater than 30 μm, and the aspect ratio of the grain of the phosphor, which is obtained by dividing the minor axis by the major axis, is not greater than 0.7.

9. The phosphor according to claim 1, wherein the excitation coefficient in the wavelength range of not longer than 460 nm is not smaller than 70% where the excitation peak intensity is defined as 100% in the wavelength range not shorter than 250 nm and not longer than 600 nm in the excitation spectrum of the phosphor.

10. The phosphor production method according to claim 1, wherein said phosphor is produced by burning a mixture of materials for said phosphor at temperature falling within the range not lower than 1200° C. and not higher than 1800° C. under nitrogen atmosphere, mixed atmosphere of nitrogen and hydrogen, or mixed atmosphere of nitrogen and ammonia.

11. The phosphor production method according to claim 1, wherein said method comprising adding an inorganic compound that exhibits a liquid phase at temperature not higher than the burning temperature to a mixture of materials for said phosphor.

12. The phosphor production method according to claim 11, wherein said inorganic compound is one of fluoride, chloride and phosphate of one or more elements selected from the group consisting of Li, Na, K, Cs, Rb, Mg, Ca, Sr, Ba and NH₃, or a mixture of two or more of said fluoride, chloride and phosphate.

13. A light emitting device comprising:
an excitation light source that emits light with peak wavelength falling within the range from near-ultraviolet light to short visible light; and
one or more types of phosphors that partially absorb light from said excitation light source, and emit fluorescent,
wherein the phosphor according to claim 1 is included in the one or more types of phosphors.

14. A light emitting device comprising:
an excitation light source that emits light with peak wavelength falling within the range from near-ultraviolet light to short visible light; and
one or more types of phosphors that partially absorb light from said excitation light source, and emit fluorescent,
wherein the phosphor according to claim 3 is included in the one or more types of phosphors.
